(19) United States
(12) Patent Application Publication
(10) Pub. No.: US 2010/0307238 A1
(43) Pub. Date: Dec. 9, 2010

(54) HUMIDITY SENSOR AND METHOD OF MANUFACTURING THE SAME

(75) Inventors: Andy Christopher VAN POPTA, Edmonton (CA); John Jeremiah STEELE, Lloydminster (CA); Michael Julian BRETT, Edmonton (CA)

Correspondence Address: Lambert Intellectual Property Law, Suite 200, 10328 - 81 Avenue, Edmonton, AB, T6E 1X2, CA

(73) Assignee: THE GOVERNORS OF THE UNIVERSITY OF ALBERTA, Edmonton (CA)

(21) Appl. No.: 12/794,543

(22) Filed: Jun. 4, 2010

Related U.S. Application Data
(60) Provisional application No. 61/184,561, filed on Jun. 5, 2009.
(60) Provisional application No. 61/185,120, filed on Jun. 8, 2009.

(51) Int. Cl. G01N 27/22; H05K 13/00

(52) U.S. Cl. 73/335.04; 29/592.1

(57) ABSTRACT

A humidity sensor comprising an insulating substrate, a moisture-sensitive layer, and at least a detection electrode contacting the moisture-sensitive layer, wherein the moisture-sensitive layer is a porous, photocatalytic metal oxide.

### CROSS-REFERENCE TO RELATED APPLICATIONS

This application claims the benefit under 35 USC 119(e) of U.S. provisional application Nos. 61/185,120 filed Jun. 8, 2009 and 61/184,561 filed Jun. 5, 2009.

### FIELD

Humidity sensors for measuring the moisture content of an atmosphere and methods of manufacturing the same.

### BACKGROUND

A conventional capacitive humidity sensor, in general, is composed of a moisture-sensitive dielectric layer interposed between a pair of electrodes. The electrodes and dielectric layer are provided on an electrically insulating support, referred to as the substrate. When the relative humidity of the atmosphere increases, water molecules enter the moisture-sensitive layer and the dielectric ratio of the layer increases. As a result, the measured capacitance between the electrodes also increases.

As shown in FIGS. 1A and 1B, a humidity sensor such as the one disclosed in U.S. Pat. No. 5,283,711 comprises a substrate 10, a moisture-impermeable conducting bottom layer as a first electrode 11, a dielectric moisture-sensitive layer 14, and a moisture-permeable conducting top layer as a second electrode 12. Appropriate circuitry and connecting wires are bonded to contact pads 13a, 13b associated with the first and second electrodes and are used to measure the change in the device capacitance upon a change in the relative humidity of the atmosphere. This type of device is often referred to as a vertically-integrated sensor and the design, while simple to manufacture, includes several drawbacks. Specifically, because the top electrode 12 of the vertically-integrated sensor is exposed to the conditions of the atmosphere, it must be very durable to such conditions. Therefore, it is preferable to use precious metals as the electrodes to ensure reliability against moisture, which consequently increases the manufacturing cost of the sensor. Furthermore, the top electrode will often inhibit the transport of water molecules from the atmosphere to the moisture-sensitive layer, which increases the response time of the sensor.

Improvements to the prior art have been made by replacing the arrangement of a bottom electrode, a moisture-sensitive layer, and a moisture-permeable top electrode, characteristic of the vertically-integrated sensor, with two electrodes that are comb-shaped and interdigitated and a humidity-sensitive layer that covers the electrodes. U.S. Pat. No. 6,742,387 describes such a capacitive humidity sensor, and as illustrated in FIGS. 2A, 2B and 2C, includes a substrate 20; a pair of comb-shaped electrodes 21, 22 that are interdigitated and face each other on the surface of a substrate on the same plane but in electrical isolation from each other; and a moisture-sensitive film 23, which covers the electrodes and an area between the electrodes. By placing the moisture-sensitive layer 23 on top of the interdigitated electrodes 21, 22, water molecules diffusing towards and away from the moisture-sensitive layer 23 are no longer impeded by a top-electrode. However, the interdigitated electrodes 21, 22 are nonetheless exposed to the conditions of the sensing environment because water moisture can reach the electrodes through the moisture-sensitive layer itself. U.S. Pat. No. 6,580,600 as illustrated in FIG. 2C describes a capacitive humidity sensor comprising two interdigitated electrodes 21, 22 opposing each other on a silicon substrate 20 with a silicon oxide film formed on a surface thereof. A moisture-sensitive film 23 is formed so as to cover the two electrodes 21, 22 with a silicon nitride film 24 interposed therebetween. The silicon nitride layer 24 is impermeable to water molecules and therefore protects the interdigitated electrodes 21, 22 from water molecules passing through the moisture-sensitive film 23.

There are many different materials used to form the moisture-sensitive layer in a capacitive sensor, including both polymers and ceramics. Candidate polymer materials include, but are not limited to, cellulose acetate, polyimide, polymethyl methacrylate, polyethersulphone, polysulfone, divinyl siloxane, benzocyclobutene, and hexamethyldisilazane. In general, humidity sensors that use polymers are either resistive-based or capacitive-based and are characterized by an increase in conductivity or permittivity when exposed to a moist atmosphere. Polymer-based humidity sensors are advantageous because they exhibit a very linear response profile over a large range of humidity levels, while drawbacks of polymers include hysteresis, sensitivity to organic vapors, and instability at high temperature and high humidity. Porous ceramic materials used in humidity sensors include anodized alumina, perovskites, spinel compounds, and other metal or semiconductor oxides. Advantages inherent to porous ceramics include mechanical strength, thermal stability, and the ability to operate at high humidity for extended lengths of time. However, humidity sensors that use porous ceramics, and to a lesser extent polymer-based humidity sensors, exhibit electrical properties that drift after long term use and must be recalibrated after a period of time. The drift in the electrical properties can be caused by a number of factors, including, but not limited to, contamination from particles of dust, oil, smoke, alcohol, and other solvents present in the atmosphere of the sensing environment. Capacitive humidity sensors that use porous materials as the moisture-sensitive layer are particularly susceptible to contamination because of the high surface area inherent to the porous moisture-sensitive layer. Re-calibration of a capacitive humidity sensor is generally undesirable because the sensor must be removed from operation and compared to a sufficient standard, which is often a costly and inefficient process.

One option to improve the life time of the humidity sensor is to periodically clean the surface of the moisture-sensitive layer by raising the temperature of the device. U.S. Pat. No. 6,812,821 describes a humidity sensor comprising an insulating substrate, detection electrodes and a moisture sensitive layer, wherein the moisture-sensitive layer is formed from a porous ceramic material such as Al₂O₃, MgCr₂O₄—TiO₂, TiO₂—V₂O₅, or ZrCr₂O₄—LiZrVO₄. Preferably, a heater is incorporated in the substrate and located just below the moisture-sensitive layer and periodically used to raise the temperature of the sensor in order to remove moisture and other impurities that have invaded the moisture-sensitive layer. In the case that the humidity is very high, dew condensation onto the sensor can also be prevented by operating the heater. However, using a heater to raise the temperature of the sensor in order to evaporate absorbed contaminants is often a slow and inefficient process. Furthermore, incorporating a heater into the body of the sensor also requires additional device integration and complicates manufacturing.

For many applications the response time of a conventional humidity sensor to sudden changes in the moisture content of the atmosphere is too slow. Current humidity sensors that are commercially available respond to abrupt changes in relative humidity in 1 to 10 seconds or longer, while many applications require humidity sensors with response times of less than 1 second. For example, the development of portable spirometers for the diagnosis of asthma and chronic obstructive pulmonary disease requires a humidity sensor with a response time of less than half a second.

Monitoring human respiration is another application that requires high speed humidity sensors. The humidity level during respiration can be used, along with other information such as temperature and air flow, to obtain a measurement of the oxygen consumption per breath. Oxygen consumption is an important monitor of normal cardiopulmonary and tissue function and is useful for body temperature control and lung hydration during anesthesia and critical care medicine. Apnea is the state of suspension of external breathing and is normally monitored using both intubated and non-intubated techniques, such as inductance plethysmography and electromyography. However, these measurements are unreliable because they suffer from motion artifacts. Rapid humidity sensors (less than 1 second response time) show promise as non-intubated apnea monitors using cyclic humidity levels in patient airflow. The need for a rapid humidity sensor is especially apparent for neonates (less than 4 weeks old) as they have respiration rates in the 45 breaths per minute range. When the respiration rate of a neonate exceeds 60 breaths per minute it can be a sign of illness and in particular, group B streptococcal infection. Detection of airway obstruction in neonates using fast humidity sensors is also receiving attention as current monitoring techniques based on sensing the movement of the chest wall may not detect airway obstruction.

The measurement of humidity in the troposphere where large humidity gradients are present requires sensors with sub-second response times. Although humidity is frequently measured through the launch of radiosondes, the spatial and temporal nature of these measurements do not capture the complexity of the three dimensional structure that governs atmospheric heating and cooling, especially for cloud development and dissipation. A fast humidity sensor mounted on an aerial vehicle would be able to obtain water vapor concentration profiles over distances of tens of meters, which is desirable for better understanding of fundamental mechanisms in the areas of atmospheric chemistry, hydrology, severe weather prediction, climate research, and polar region studies.

### SUMMARY

In one embodiment, there is provided a humidity sensor comprising an insulating substrate, a moisture-sensitive layer, and at least a detection electrode contacting the moisture-sensitive layer, wherein the moisture-sensitive layer is a porous, photocatalytic metal oxide. Various electrical characteristics may be used for detection of humidity, such as capacitance, resistance, impedance magnitude and phase angle. For a capacitive sensor, two detection electrodes are used at a minimum. For a resistive sensor, only one electrode is required, although an embodiment of a resistive sensor may use more than one electrode.

In another embodiment, a capacitive humidity sensor includes a substrate, a pair of detection electrodes, a moisture-sensitive layer, and a source of light radiation.

In an embodiment of a dual electrode configuration, the electrodes may be formed of two comb-shaped interdigitated electrodes in the same plane on the surface of the substrate. The electrodes may be countersunk into the surface of the substrate to produce a planarized surface onto which the moisture-sensitive layer may be formed. To protect the electrodes from water molecules that penetrate through the moisture-sensitive layer, a passivation layer may be formed on top of the interdigitated electrodes, which also helps in planarizing any surface features that may still be present after countersinking the electrodes.

Countersinking the electrodes creates a flat surface on the substrate which is important when the moisture-sensitive layer is a porous metal-oxide thin film formed by an oblique-angle physical vapor deposition process.

In a further embodiment, a method of manufacturing a moisture-sensitive layer includes forming a porous metal-oxide layer using oblique-angle physical vapor deposition (PVD) or glancing angle deposition (GLAD).

When the moisture-sensitive layer of a humidity sensor according to any embodiments disclosed herein is formed from a photocatalytic metal-oxide, a method is also provided in which the humidity sensor may be cleaned by exposing the humidity sensor to photocatalytic radiation.

However, it should be understood that the detailed description and specific examples, while indicating preferred embodiments of the invention, are given by way of illustration only, since various changes and modifications within the spirit and scope of the invention will become apparent to those skilled in the art from the detailed description.

### BRIEF DESCRIPTION OF THE DRAWINGS

The humidity sensor is illustrated by reference to the drawings in which:

FIG. 1A is a schematic of a prior art vertically-integrated humidity sensor design in a sectional top view, and FIG. 1B is a cross-sectional view of the same.

FIG. 2A is a schematic of a prior art humidity sensor using interdigitated electrodes in a sectional top view, and FIG. 2B is a cross-sectional view of the same. FIG. 2C shows the same humidity sensor design concept represented in FIG. 2B but with an additional passivation layer.

FIG. 3 is a schematic of the glancing angle deposition apparatus, which is known in itself, but novel with respect to the use described in this document.

FIG. 4A is a schematic of a humidity sensor in a cross-sectional view, FIG. 4B is a cross-sectional view of the same but with an additional passivation layer, and FIG. 4C shows an embodiment of a resistive based humidity sensor.

FIG. 5A and FIG. 5B are graphs respectively showing the series and parallel capacitance response at 0.1 kHz, 1 kHz, and 10 kHz of a humidity sensor as disclosed herein when exposed to changes in relative humidity.

FIG. 6 is a graph showing the transient response of a humidity sensor as disclosed herein when exposed to a pulse of wet air at flow rates of 0.5 LPM, 1 LPM, and 2.5 LPM.

FIG. 7 is a graph showing the change in the capacitive response of a humidity sensor as disclosed herein after a period of ageing.

FIG. 8 is a graph showing the capacitive response of a humidity sensor as disclosed herein after periodic exposures to UV irradiation.

FIG. 9 is a graph of the UV spectral irradiance used to expose a humidity sensor as disclosed herein and produce the capacitive response curves shown in FIG. 8.

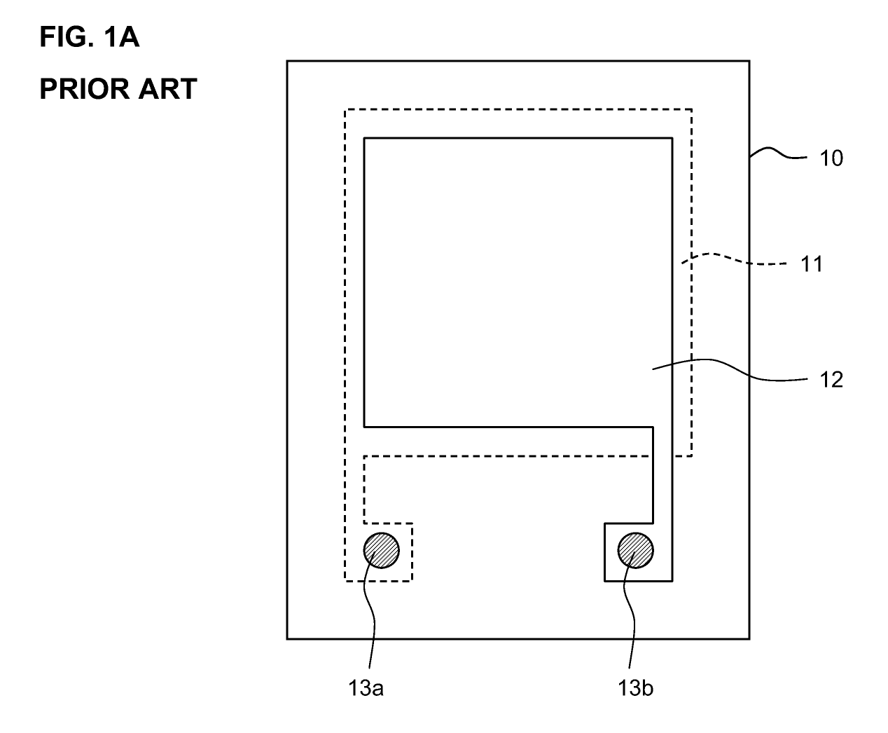

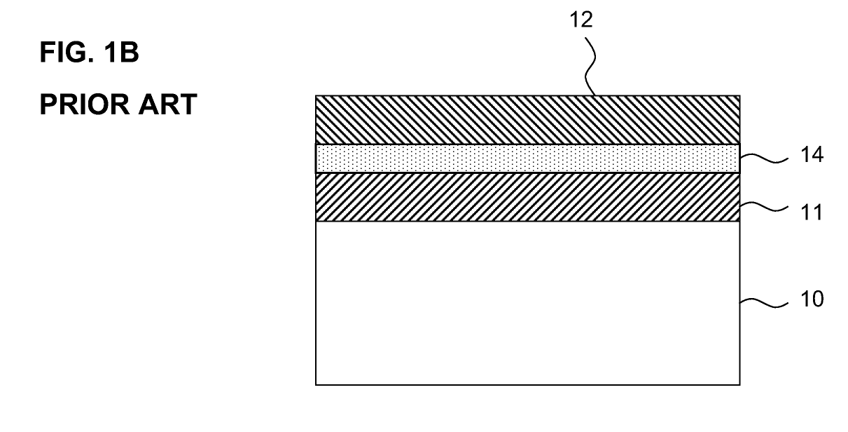

### DETAILED DESCRIPTION

Specific embodiments of the present invention will now be described hereinafter with reference to the accompanying figures in which the same or similar component parts are designated by the same or similar reference numerals. Immaterial modifications may be made to the embodiments described here without departing from what is covered by the claims.

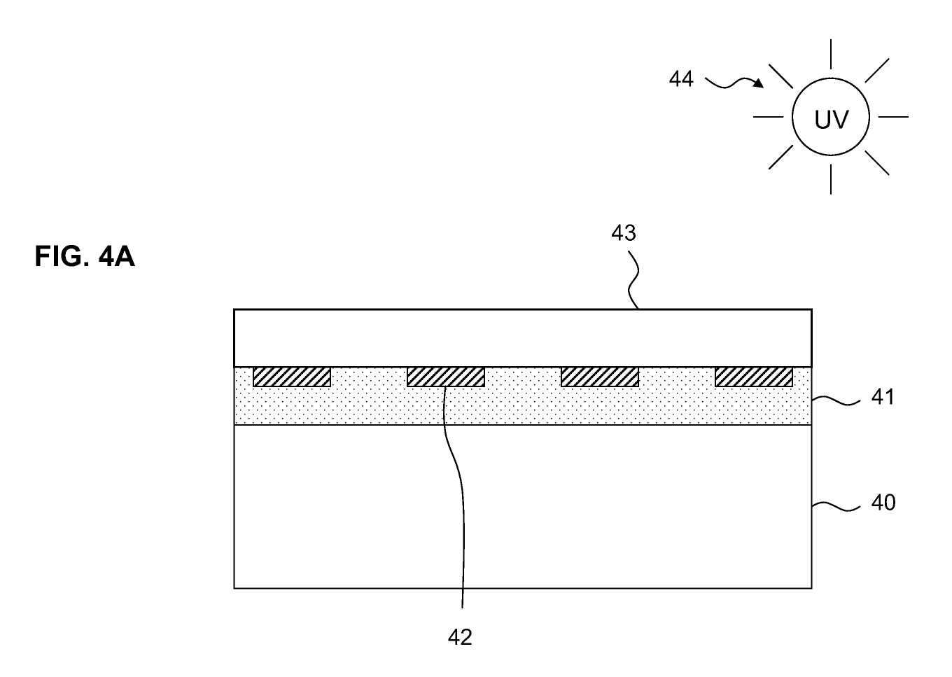

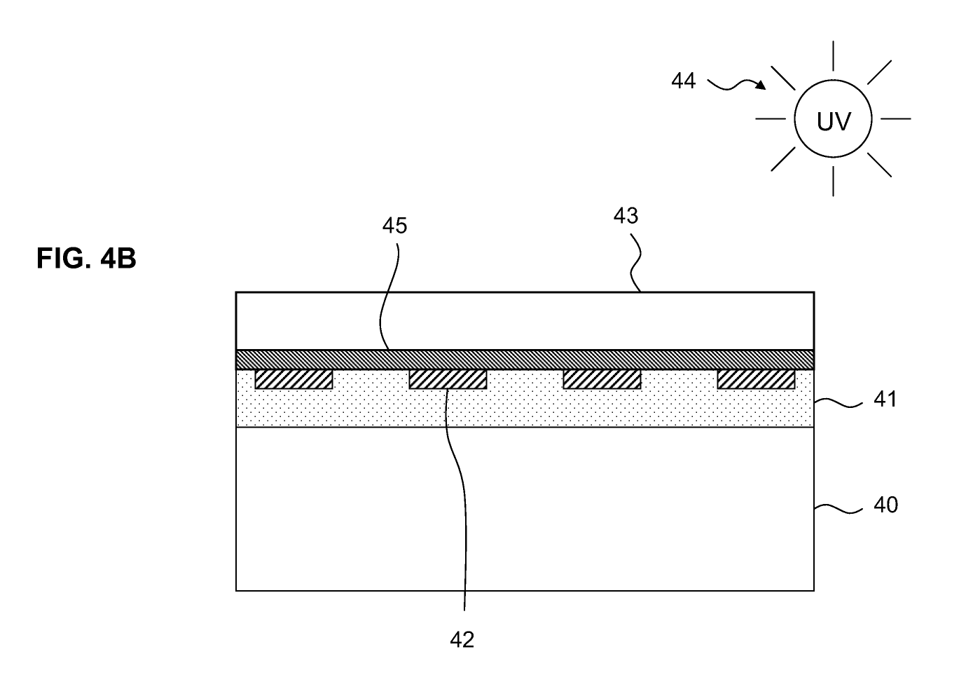

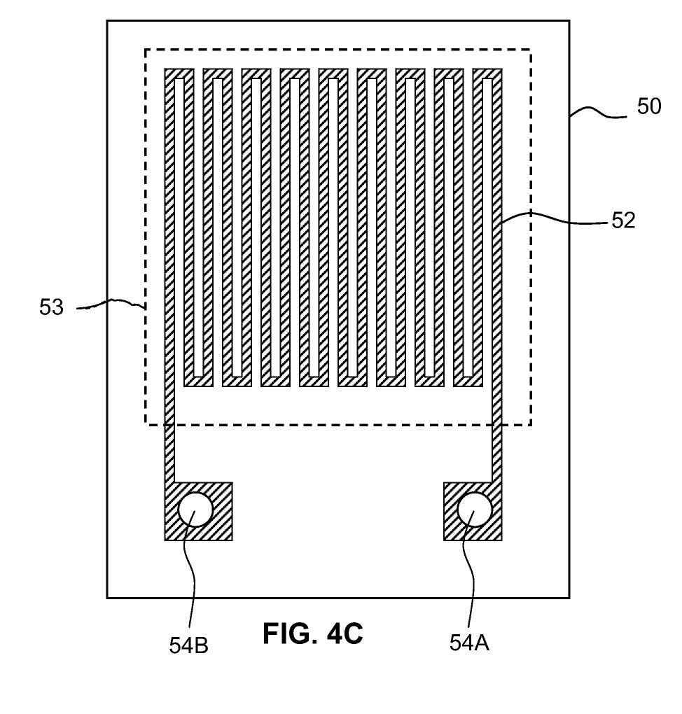

Referring to FIG. 4A, there is shown a capacitive humidity sensor comprised of a porous, metal-oxide, moisture-sensitive layer 43 formed on a pair of comb-shaped, interdigitated electrodes 42 that are planarized on the surface of a substrate 40. The metal-oxide moisture-sensitive layer 43 is designed with a thickness, porosity, and pore size distribution that results in a rapid response time to sudden changes in relative humidity. The moisture-sensitive layer 43 is also formed from a photocatalytic material so that light of the appropriate wavelength and intensity can be used to stimulate photocatalysis and initiate a chemical reaction that decomposes organic contaminates present on the surface of the pore walls within the moisture-sensitive layer. The process of photocatalysis cleans the surface of the moisture-sensitive layers and stabilizes the associated electrical properties of the humidity sensor layer, thereby improving the performance of the device under long term use.

A source of photocatalytic radiation 44 may be used to clean the moisture sensitive layer. The substrate 40 provides a simple rigid support for the other components of the sensor. It is preferable for the substrate 40 material to be compatible with standard semiconductor processing for ease of fabricating the subsequent electrode layer and moisture-sensitive layer. The electrode layer is composed of two comb-shaped interdigitated electrodes 42 in the same plane on the surface of the substrate. It is preferable for the electrodes 42 to be countersunk into the surface of the substrate to produce a planarized surface onto which the moisture-sensitive layer may be formed. If the substrate is a semiconductor material such as silicon, it is preferable for the electrodes to be countersunk and planarized with a silicon dioxide layer on the silicon die. The silicon dioxide provides electrical isolation between the various electrode lines. It is preferable for the dimensions and separation distance of the comb-shaped interdigitated electrodes to be chosen to concentrate the electric field density in the moisture-sensitive layer. The geometry of the electrodes alters the electric field profile within the sensing medium and significantly affects the performance of the device. In particular, to maximize the change in capacitance of the sensor when water molecules enter or leave the moisture-sensitive layer, the distance between parallel electrode lines should be approximately equal to the thickness of the moisture-sensitive layer. To protect the electrodes from water molecules that penetrate through the moisture-sensitive layer, a passivation layer may be formed on top of the interdigitated electrodes, which also helps in planarizing any surface features that may still be present after countersinking the electrodes.

Countersinking the electrodes creates a flat surface on the substrate which is important when the moisture-sensitive layer is a porous metal-oxide thin film formed by an oblique-angle physical vapor deposition process.

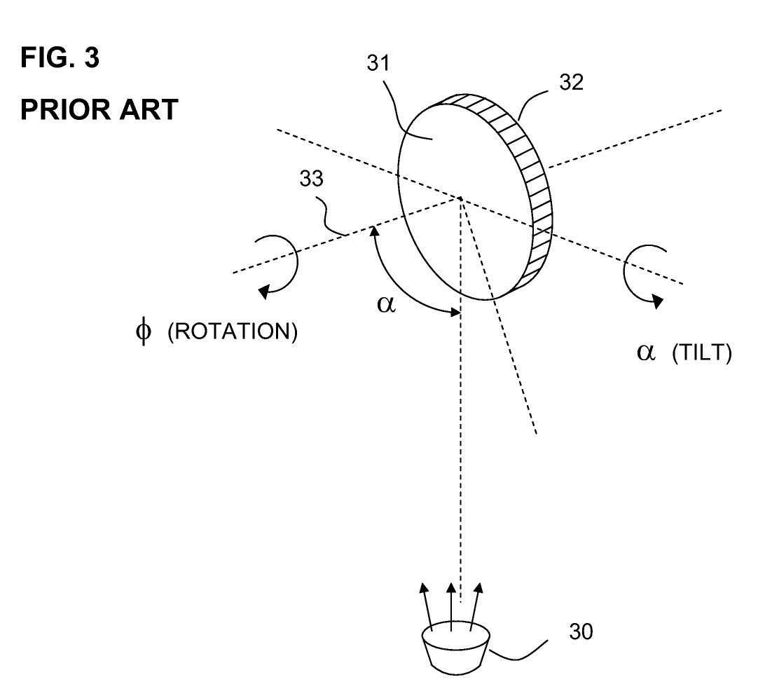

A method of manufacturing a moisture-sensitive layer includes forming a porous metal-oxide layer using oblique-angle physical vapor deposition (PVD) or glancing angle deposition (GLAD). These are known processes, and the GLAD process is disclosed in U.S. Pat. No. 5,866,204, and illustrated in FIG. 3. The GLAD process is a method of depositing shadow sculpted thin films by rotating the substrate to be coated in the presence of an obliquely incident vapor flux. Two motors are used to rotate the substrate about an axis normal to the surface of the substrate and/or parallel to the surface of the substrate. The resultant thin film is composed of a plurality of columns extending from the surface of the substrate. The overall porosity is determined by the spaces between columns and pores along the surface of individual columns. The PVD process is carried out in conditions where the vapor flux arrives at the substrate in approximately a straight line and the material used has a high sticking co-efficient to limit the diffusion of incident vapor molecules. During the initial stages of thin film growth, nucleation sites shadow regions of the substrate surface from the incident vapor flux. Instead of coalescing to form a continuous thin film layer, the self-shadowing growth causes the nucleation sites to develop into isolated columns, where the center axis of each column is inclined at angle from the substrate normal and grows in a direction favoring the incoming vapor flux. The shape of the columns, as well as the range and frequency of different pore sizes, can be controlled through the appropriate use of substrate rotation, as described by the prior art. The GLAD process is capable of forming a wide variety of metal-oxide thin films which can be used to form the moisture-sensitive layer of a humidity sensor. The advantage of using GLAD is that very porous thin films can be formed with a large range of different pore sizes and geometries. The resultant thin film layer will also exhibit a large surface area which increases the sensitivity of the moisture-sensitive layer to water vapor. In a polymer-based humidity sensor, water vapor that is absorbed in the moisture-sensitive layer typically produces a small change in capacitance or resistivity. However, when water vapor adsorbs onto the pore walls of a metal oxide layer with a high surface area, the capacitive or resistive change can exceed many orders of magnitude. The greater sensitivity can be attributed to the nanoscale surface interactions between the water molecules and the oxide surface, as opposed to the bulk absorption of water molecules inside a polymer layer.

Furthermore, the spaces between isolated columns are generally interconnected and highly accessible to water molecules from the surrounding atmosphere. The low tortuosity of these pores encourages rapid diffusion of water molecules between the surfaces of the thin film columns and the surrounding atmosphere, which causes a very fast sensor response to sudden changes in relative humidity for sensors utilizing GLAD-produced thin film materials. However, the high porosity and large surface of the metal-oxide moisture-sensitive layer also increases the potential for contamination by air-borne particles present in the atmosphere. Dust, smoke, and volatile organic compounds can adsorb onto the surfaces of the porous thin film and gradually change the characteristic response of the humidity sensor over time. Without proper re-calibration or treatment, sensor contamination can lead to erroneous measurements of the ambient humidity.

When illuminated by light of a particular frequency, the metal-oxide layer 43 generates electron-hole pairs that can react in humid air to form hydroxyl radicals and superoxide ions. Both are powerful oxidizing agents that will convert volatile organic compounds on the surface of the photocatalyst into CO₂ and H₂O. It is preferable for the metal-oxide to be TiO₂ because it is widely available, resistant to corrosion, and requires minimal processing to manufacture. Photocatalysis can be used to clean the surface of TiO₂ when exposed to radiation in the UV range of 300-400 nanometers (nm) of the electromagnetic spectrum. Sources of UV radiation may include natural sources, such as sunlight, or artificial sources such as a black light or UV LED (light-emitting diode). The UV light source may be incorporated into the humidity sensor itself or may be external to the sensor or simply a by-product of the ambient lighting. While it is preferable to use TiO₂ as the photocatalyst, it may also be acceptable to use alternative metal-oxide compounds, including, but not limited to, iron oxides, silver oxides, copper oxides, tungsten oxides, zinc oxides, zinc/tin oxides, strontium oxides, and mixtures therefore. The metal oxide may also include superoxides or suboxides of the metal, and may also be doped to change the range of wavelengths that can be used to stimulate photocatalysis. For example, S. U. M. Khan, M. Al-Shahry, and W. B. Ingler Jr., “Efficient photochemical water splitting by a chemically modified n-TiO₂,” Science 297, pp. 2243-2245 (2002), describes synthesizing a chemically modified n-type TiO₂ by controlled combustion of Ti metal in a natural gas flame to reduce the bandgap to 2.32 electron volts, so that visible light below a wavelength of 535 nanometer is be absorbed.

An exemplary humidity sensor contains a substrate 40, detection electrodes 42, and a moisture-sensitive layer 43 formed from a porous metal-oxide thin film that produces photocatalytic activity when exposed to light of the appropriate wavelengths.

FIG. 4A shows a cross-section of a humidity sensing element in a preferred embodiment. No particular limitations are imposed on the substrate 40, which provides a rigid support for the other components of the humidity sensor and may be formed using a number of materials, including glass, ceramics, or plastic resin. It is preferable to use a semiconductor material, such as silicon, to form the substrate, so that it is compatible with certain semiconductor processing techniques that may be used in subsequent manufacturing steps. No particular limitations are imposed on the thickness and planar dimensions of the substrate, but it is preferable for the substrate to cut into dies from a silicon wafer; the silicon wafer having a thickness of 0.1 to 1.0 mm and a diameter of 25 to 300 mm.

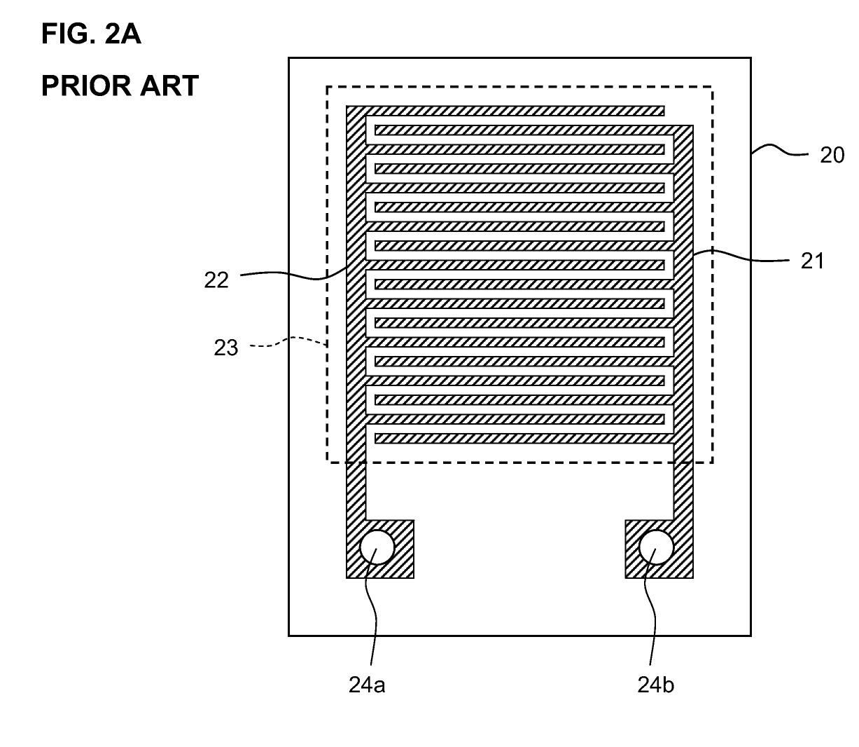

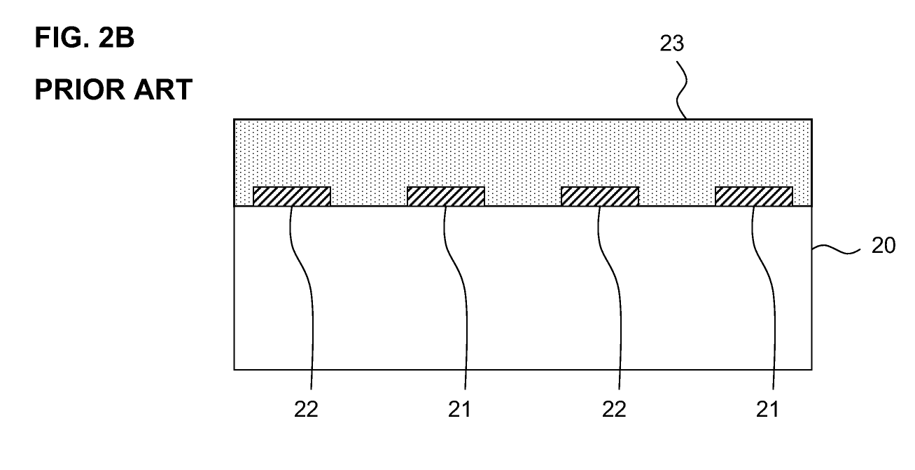

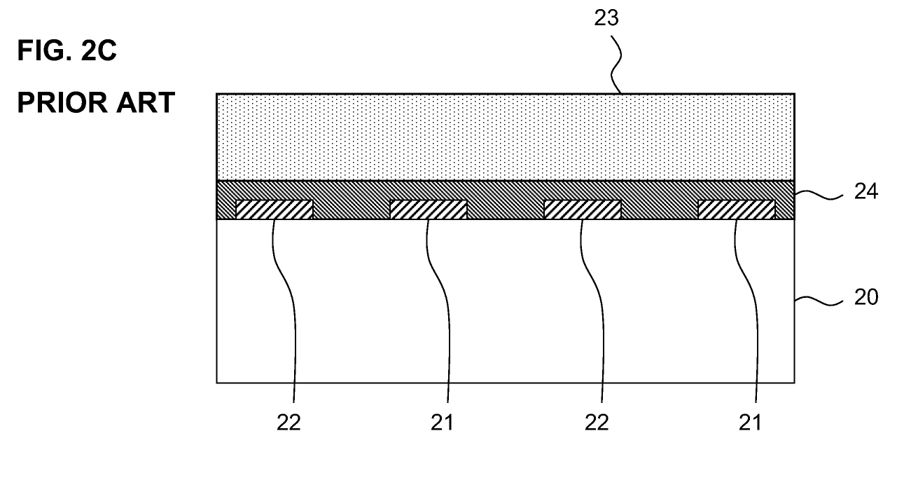

The interdigitated electrodes 42 may formed by a number of standard semiconductor processing techniques, and may have a variety of configurations, such as shown in FIG. 2C. For example, if a silicon wafer is used, an oxide layer 41 is first formed by thermal oxidation to provide electrical isolation for the subsequent electrode lines. A photoresist layer is then applied and patterned through a mask using photolithography. The pattern is then transferred to the underlying oxide layer using an appropriate etching process to a sufficient depth to form wells for the electrode lines. The metal electrode lines are then deposited through the photoresist masking layer into the oxide wells. Materials that are compatible with normal semiconductor processing should be used, for example, Al, Al—Si, Ti, Au, Cu, poly-Si or the like. The electrode deposition may include the application of an initial adhesion layer prior to metallization, such as a layer of Cr. Finally, the photoresist layer is removed to lift-off excess metal, leaving behind only the countersunk electrode lines. Alterations to the process steps with the intent of forming appropriate interdigitated electrode lines may be made by someone skilled in the art. The geometry of the interdigitated electrodes 42 determines the electric field profile within the moisture-sensitive layer 43 and therefore plays an important role in sensor performance. The dimensions of the interdigitated electrodes 42 may assume a range of values depending on the nature of the humidity sensor, the particular parameters of the moisture-sensitive layer 43 and the application of the humidity sensor. Although the shape of the detection electrodes is not restricted, in the preferred embodiment, the electrodes have a comb-shaped pattern constituted by plural electrode portions that each have rectangular fingers that extend in parallel interlocking lines from a common bus electrode. It is preferable for the width of the electrode lines to be 100 nm to 100 microns and the space between neighbouring electrode lines to be 100 nm to 100 microns. It is further preferable for the electrode lines to be 1 to 10 microns in width and the separation between electrode lines to be 1 to 10 microns. It is preferable for the thickness of the electrode lines to be 50 nm to 1 micron and the length of the electrode lines to be 1 to 10 mm. The area covered by the interdigitated electrodes depends on the dimensions of the electrode lines and the number of individual electrode lines and must be sufficient is size to provide an appropriate change in the device's electrical characteristics when the moisture-sensitive layer is exposed to water vapor for the associated measurement circuitry. It is preferable for interdigitated electrodes to occupy a planar area on the substrate between 1 mm² and 100 mm². Contact pads and integrated circuitry may also be incorporated into the substrate and connected to the interdigitated electrodes using compatible semiconductor processing techniques.

According to a second embodiment, a passivation layer 45 is deposited onto the countersunk electrodes 42 to protect the underlying metallic layers from long term exposure to the environment. For example, a silicon nitride film, having a thickness of 10 nm to 1 micron may be used as a second insulating layer. This additional coating 45 is applied after forming the interdigitated electrodes 42 but before depositing the moisture-sensitive layer 43.

The moisture-sensitive layer 43 comprises a porous, metal-oxide, thin film formed over the interdigitated electrodes by an appropriate deposition process. It is preferable to use oblique-angle physical vapor deposition (PVD) to create a metal-oxide thin film that exhibits a large network of interconnected pores with a wide pore size distribution. The moisture-sensitive material should undergo a large change in its effective dielectric constant when exposed to a humid environment and photocatalytic activity when illuminated by light of the appropriate wavelengths

Oblique-angle PVD is generally performed by evaporating a source of solid material 30 by resistive or electron-beam heating within a vacuum system. Other deposition methods such as pulsed laser deposition or sputtering may also be used. As the source material 30 is evaporated, vapor molecules travel through the vacuum system and condense onto the substrate 32 to form a thin film layer. Under conditions of limited adatom diffusion (when the substrate temperature, Tₛ, is small relative to the bulk melting temperature of the source material, Tₘ—typically T_{S}/Tₘ<0.3—both in Kelvin) the initial stages of film growth are characterized by the formation of nucleation sites on the surface of the substrate 31. When the substrate 32 is tilted at an oblique angle to the impinging vapor stream, the nucleation sites shadow regions of the substrate surface and develop into a series of individual columns instead of coalescing to form a ubiquitous thin film layer. The columnar growth will occur in a direction biased towards the vapor source 30 and generally results in the creation of a porous, tilted columnar morphology. By rotating the substrate 32 during the thin film deposition process it is possible to change the effective location of the vapor source 30 in the reference frame of the substrate 32 and therefore shape the columns into a variety of different structures. For example, a chevron-like microstructure composed of alternating layers of tilted columns can be formed by periodically rotating the substrate by 180° about the substrate normal 33. A microstructure composed of vertically-inclined columns can be formed by rapidly and continuously rotating the substrate about the substrate normal 33. The spaces between the columns form a large interconnected network of pores within the thin film matrix. These pores are relatively large and readily extend to both the substrate and outer thin film surfaces. Pores on the exterior of individual columns may also exist and are typically much smaller in size relative to the large pores between columns. A detailed description of the oblique-angle vapor deposition technique used to create shadow-sculpted thin films can be found in the prior art. In particular, the invention disclosed in U.S. Pat. No. 5,866,204.

Oblique-angle PVD is compatible with a large range of materials, including many dielectrics, semiconductors, metals, and organic compounds. In an embodiment, using oblique-angle PVD provides a moisture-sensitive layer which undergoes photocatalysis in order to create a humidity sensor that can be regenerated through simple light irradiation. Therefore, it is preferable to use source material that has photocatalytic properties or source material that can be made into a photocatalyst using an appropriate dopant or reactive evaporation step. For example, but not limiting, the photocatalytic thin film may include one or more metal-oxides such as titanium oxides, iron oxides, silver oxides, copper oxides, tungsten oxides, zinc oxides, zinc/tin oxides, strontium oxides, and mixtures thereof. The metal oxide may include oxides, superoxides, or suboxides of the metal. It is preferably to use TiO₂ which is a robust, stable, and widely available metal-oxide compound that is well-known for its photocatalytic properties and can be used as a moisture-sensitive material in a humidity sensor.

In a preferred embodiment, oblique-angle PVD is used to form the moisture-sensitive layer. The deposition angle, as measured from the substrate normal, should be between 50° and 89°. It is more preferable for the deposition angle to be in the range of 70° to 85°. A deposition angle that is too small will produce a thin film with very low porosity and a small range of pore sizes, resulting in low sensitivity to water vapor. A deposition angle that is too large will lead to unstable and non-uniform thin film growth and will lower the efficiency of the deposition process. The moisture sensitive layer should be grown to a thickness of 10 nm to 50 microns. It is more preferable for the moisture sensitive layer to be grown to a thickness of 500 nm to 5 microns. A film thickness that is too small will provide insufficient surface area for water adsorption and will limit the magnitude of the electrical response of the moisture-sensitive layer when exposed to moist air. A film thickness that is too large will lead to mechanical stress between the thin film and the substrate and will generally result in a highly non-uniform thin film microstructure due to the inherently unstable growth process characteristic of oblique-angle PVD. The preferred film thickness is generally related to the dimensions of the interdigitated electrodes and should be chosen to maximize the electric field density applied by the interdigitated electrodes within the physical space occupied by the moisture-sensitive layer. The thin film microstructure imparted by the use of substrate rotation during the deposition process should provide a large pore size distribution, minimal pore tortuosity and a large internal surface area. It is preferable to form a thin film microstructure that includes pores that range in size from nanopores (<2 nm in diameter) to macropores (>50 nm in diameter). This ensures that the moisture sensitive layer will remain responsive under a wide range of humidity levels, temperatures, and pressures. When all the pores are interconnected and exhibit a low degree of pore tortuosity, water molecules can rapidly diffuse into and out of the thin film microstructure to adsorb and desorb onto and from the pore walls, improving the response time of the sensor. The surface area should also be maximized to increase the sensitivity of the thin film to adsorbed water molecules. The electrical response of the humidity sensor is dependent on the relative change in the capacitance or impedance of the moisture-sensitive layer. A layer with a larger surface area can accommodate more adsorbed water molecules and will exhibit a relatively larger electrical response.

As the internal surfaces of the moisture-sensitive layer become contaminated by air-borne organic pollutants, the characteristic response of the sensor will change and drift over time. To restore the surface of the moisture-sensitive layer, the sensor is exposed to light of the appropriate wavelengths. Upon irradiation for a sufficient time with a sufficient intensity of light having a wavelength which has an energy higher than the bandgap energy of the photocatalytic moisture-sensitive layer, absorbed photons create electron-hole pairs that react in humid air to form hydroxyl and peroxy radicals on the surface of the moisture-sensitive layer. The radicals oxidize the organic contaminant molecules, breaking them down into H₂O and CO₂. For a photocatalytic material such as TiO₂, a dose of UV light can be used to initiate the photocatalytic reaction. Candidate sources of UV light 44 include, but are not limited to, fluorescent lamps, incandescent lamps, metal halide lamps, mercury lamps or other types of indoor illumination external to the humidity sensor as defined by the substrate, electrodes, and moisture-sensitive layer. In a situation where the photocatalytic coating is exposed to sunlight, the photocatalyst may be photoexcited spontaneously by the UV light contained in the sunlight. The light source 44 may also be integrated into the sensor design using an appropriate light-emitting diode or similar UV emitter which can be packaged with the sensor and powered by the associated circuitry. The necessary dose levels, exposure times, and duty cycle depend on the parameters of the moisture-sensitive layer, the nature of the light source, and the conditions of the sensing environment.

The humidity sensor is used with conventional humidity sensor electronics modified to accommodate the response of the particular moisture sensitive material used in the intended application. Thus, for example, since some photocatalytic moisture sensitive materials have a non-linear response to moisture, the electronics will need to be adjusted to accommodate the non-linear response.

A capacitive humidity sensor requires two opposed electrodes as shown in FIGS. 4A and 4B, and many different configurations are possible. Making the two electrodes into an interdigitated or comb shape places the electrodes in close proximity to one another and concentrates the electric field inside the thin film material.

An alternative electrode configuration which is not interdigitated may also be used in a capacitive sensor, and may also be used in resistive-based humidity sensor. A resistive-based humidity sensor is made in the same manner as the capactive-based humidity sensor as shown in FIG. 4A for example, but the detection electrodes need not comprise separate electrodes as in the capacitive humidity sensor. In a resistive humidity sensor as shown in FIG. 4C, a substrate 50 has an serpentine electrode 52 formed on it in the same manner as the interdigitated electrodes, with a moisture sensitive layer 53 formed over the top of the electrode 52 in the same manner as in the case of the interdigitated electrodes. The serpentine electrode 52 extends between contact pads 54a and 54b. Electronics for the sensor measure resistance to determine humidity. Other configurations of electrode may also be used for the electrode 52. Although humidity sensors are shown in FIGS. 4A-4C for use in particular as capacitive and resistive sensors, various electrical characteristics may be used for detection of humidity, such as capacitance, resistance, impedance magnitude and phase angle. For impedance and phase angle measurements, the electrode configurations disclosed for capacitive sensors may be used, with appropriate modifications of the sensor electronics to measure impedance or phase angle characteristics rather than capacitance.

The following example of a humidity sensor is presented for illustration and the humidity sensor is not limited thereto.

### Example

The response of a humidity sensor incorporating a photocatalytic, porous, TiO₂ moisture-sensitive layer, manufactured by glancing angle deposition, was investigated as follows. A partially oxidized silicon wafer was patterned by standard photolithography to include two gold interdigitated electrodes. The individual digit width was 3 microns, the digit length was 10 millimeters, the digit thickness was 120 nm, and the separation between neighboring digits was 5 microns. There were 1250 digits in total, covering a planar sensing area of 100 mm². The interdigitated electrodes were countersunk in the silicon dioxide layer and planarized to create a flat surface for the subsequent thin film deposition step. Contact pads were also included to interface with external measurement circuitry. Using interdigitated electrodes that are countersunk ensures uniform thin film growth in the plane of the substrate during oblique-angle PVD. Any topology imparted by the electrode digits would otherwise bias the substrate shadowing and cause unwanted variations in planar coverage of the thin film. Depending on the height of the electrode digits and the deposition angle, entire regions of the planar sensing area would remain uncovered.

The moisture-sensitive layer was applied using glancing angle deposition. The substrate was placed inside an electron-beam evaporation system at a deposition angle of 81° (measured relative to the substrate normal) and rotated about the substrate normal at a rate of 6 to 9 RPM. The deposition pressure was maintained between 6-8×10⁻⁵ Torr in a partial pressure of O₂(g). The source material was rutile TiO₂, evaporated at a deposition rate of 0.5-0.7 nm/s, and the thin film was grown to a thickness of 1.5 microns. The continuous substrate rotation produced a thin film columnar microstructure consisting of vertically-inclined columns. No substrate heating was used and x-ray diffraction analysis revealed a primarily amorphous TiO₂ crystal structure.

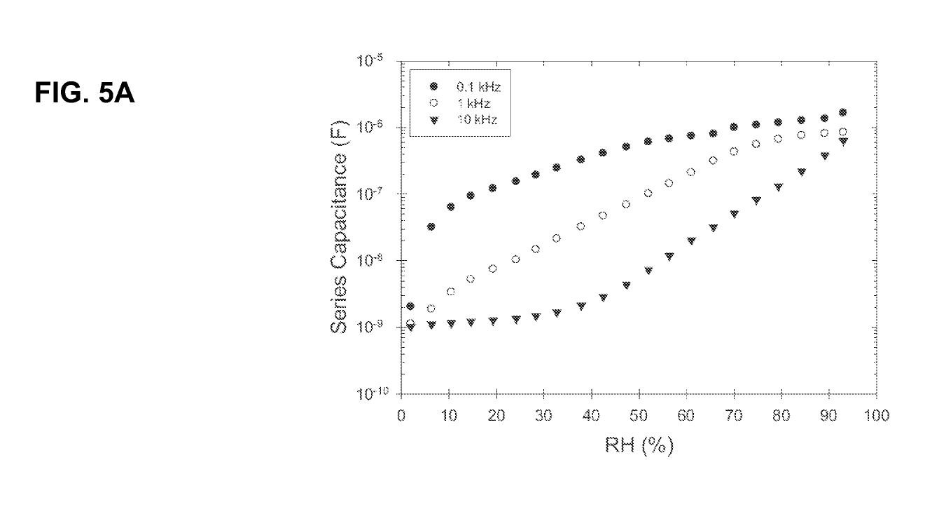

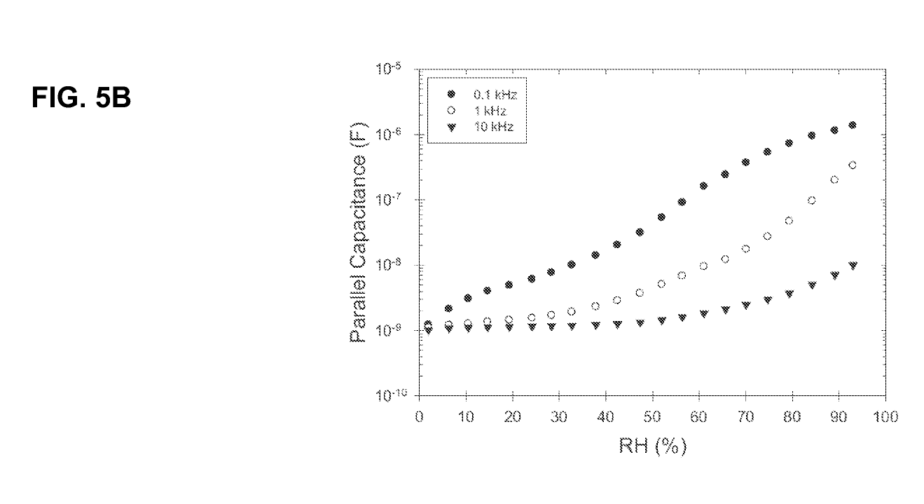

The LCR meter used to measure the electrical response of the sensor to changes in ambient humidity used 4-terminal connections to the device under test (DUT), where one set of terminals applied an AC current and the other measured the resulting open-circuit voltage. This eliminated measurement errors from lead inductance and lead resistance (including contact resistance) in series with the device and stray capacitance between the two leads. Measurement of the current, voltage, and their phase angle difference provided the meter with all the necessary information to calculate a number of impedance parameters using either a series or parallel equivalent circuit model. For series equivalent circuit measurements, the meter models the DUT as a resistance in series with either a capacitance or inductance. The parallel setting models the DUT as a resistance in parallel with a capacitance or inductance. A real capacitor can be modeled by an inductance, in series with a resistance, in series with a parallel combination of a capacitance and resistance. However, for most capacitive elements the series inductance can be safely ignored unless particularly high frequencies are used where self resonant characteristics become an issue. The series resistance represents the effects of conductor resistance and dielectric losses. The parallel resistance represents the effects of leakage current through the electrodes of the capacitor. Both the series capacitance and the parallel capacitance of the humidity sensor utilizing the described TiO₂ moisture-sensitive layer are presented in FIG. 5A and FIG. 5B at frequencies of 0.1 kHz, 1 kHz, and 10 kHz.

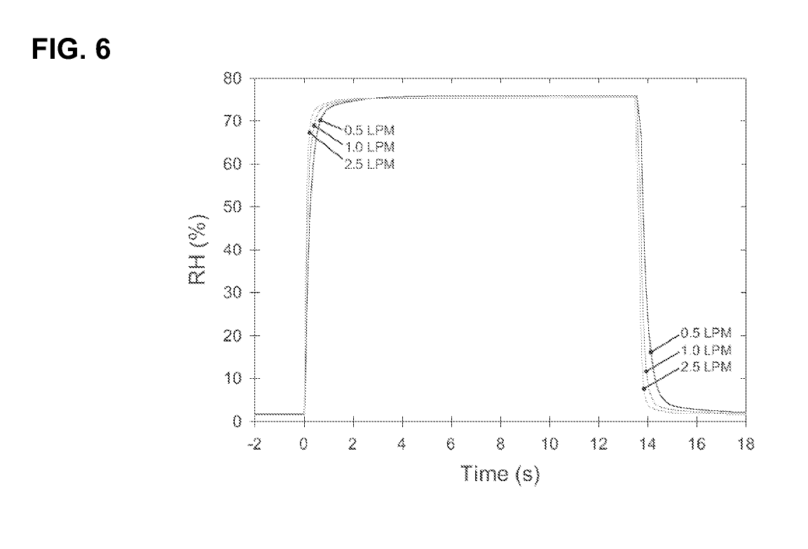

To test the response time of the humidity sensor, two diverting solenoid valves were used to alternate the flow of air onto the DUT between dry nitrogen (<1% RH) and moist air (variable RH). The actuation time of the solenoid valves was between 2 and 3 ms and the volume of air to be exchanged per adsorption/desorption event was calculated to be 2.0-2.5 mL. Thus, for a 2.5 LPM (liters per minute) flow rate the gas exchange will occur in 50-60 ms, assuming no mixing. Flow rates were typically held at 2.5 LPM during response time measurements using flowmeters. The sensor capacitance (or other impedance parameter) during response time measurements was monitored by the LCR meter. FIG. 6 shows response time data obtained at three different flow rates (0.5, 1.0, 2.5 LPM) collected during a 13.5 s pulse (low RH to high RH to low RH). The reported response times are defined as the time it takes for 90% of the total change in capacitance to occur during the absorption or desorption of water vapor. At a flow rate of 0.5 LMP, the adsorption time was 590 ms and the desorption time was 775 ms. At a flow rate of 1.0 LMP, the adsorption time was 375 ms and the desorption time was 426 ms, and at a flow rate of 2.5 LPM, the adsorption time was 243 ms and the desorption time was 336 ms. The longer response times for the smaller flow rates are a direct result of longer extrinsic times required to change the humidity at the sensor surface since the same sensor was used to obtain all measurements. We estimated that these response times encompass a 90 ms contribution from the experimental setup.

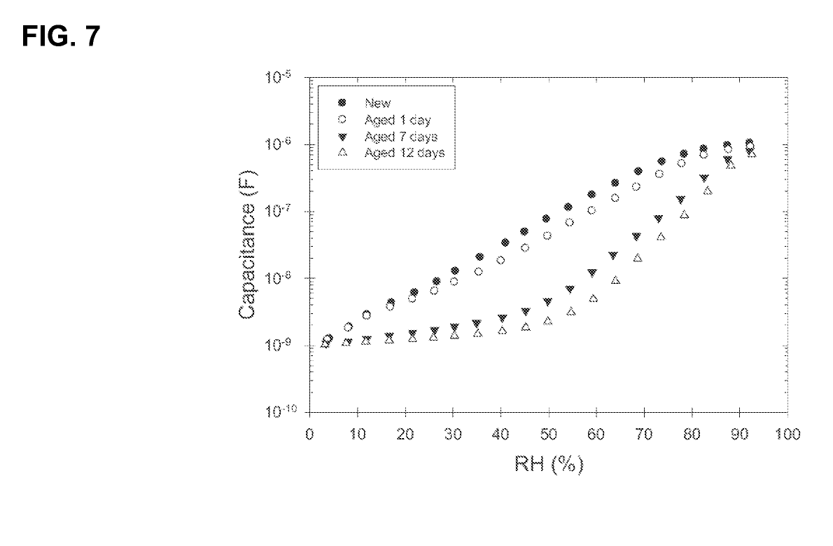

FIG. 7 shows the capacitive response over several days of exposure to the open air for the 1.5 μm thick TiO₂ vertical post film. After only one day the sensor response was noticeably different. After one week the capacitive response had significantly degraded, becoming much less sensitive to relative humidity levels below 40%. Continued ageing further diminished sensor performance and increased the relative humidity where the sensor becomes exponentially responsive. The degradation of the capacitive response is expected to be from environmental contamination common to porous materials.

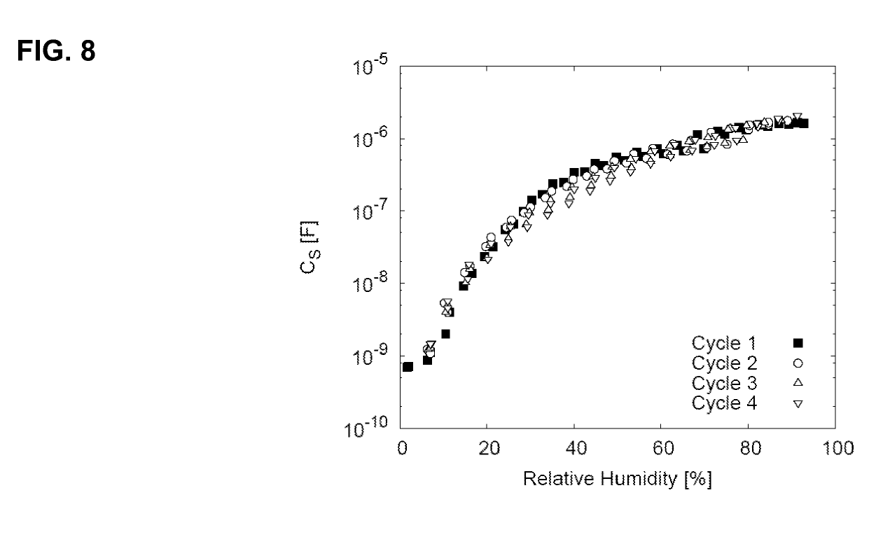

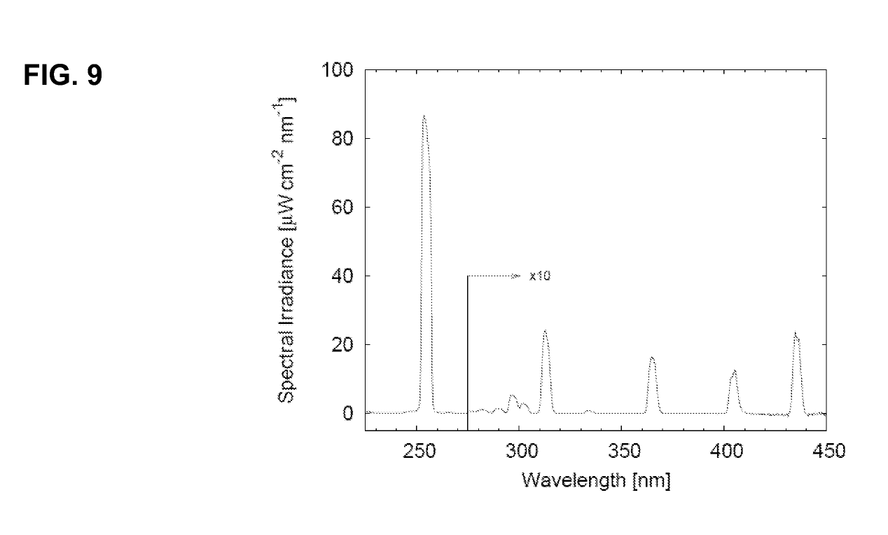

To regenerate the characteristic response of the moisture-sensitive layer after environmental contamination, sensors were exposed to an 8 Watt UV lamp, placed 4.5 cm above the sensor surface. The spectral irradiance of the UV lamp was measured using a compact CCD spectrometer which was calibrated using a Hg lamp with a spectral lamp power supply. The spectra irradiance at the sensor is shown in FIG. 9 (the spectral irradiance was multiplied by a factor of 10 for wavelengths greater than 275 nm). No ozone was detected inside the chamber, using a single-gas detector as a sensor. FIG. 8 shows the results of repeated UV exposures on the humidity sensor. Between exposures, the sensor is allowed to age over a period of 10 to 20 days before being irradiated by the UV lamp. After each exposure, the response of the sensor returns to the initial state, demonstrating the usefulness and repeatability of the humidity sensor.

In the claims, the word “comprising” is used in its inclusive sense and does not exclude other elements being present. The indefinite article “a” before a claim feature does not exclude more than one of the feature being present. Each one of the individual features described here may be used in one or more embodiments and is not, by virtue only of being described here, to be construed as essential to all embodiments as defined by the claims.

What is claimed is:

1. A humidity sensor comprising an insulating substrate, a moisture-sensitive layer, and at least a detection electrode contacting the moisture-sensitive layer, wherein the moisture-sensitive layer is a porous, photocatalytic metal oxide.

2. The humidity sensor of claim 1 in which the at least a detection electrode comprises a pair of electrodes, and the humidity sensor is a capacitive humidity sensor.

3. The humidity sensor of claim 2 in which the pair of detection electrodes are interdigitated.

4. The humidity sensor of claim 3 in which the detection electrodes are each comb shaped.

5. The humidity sensor of claim 1 in which the at least a detection electrode is a single electrode and the humidity sensor is a resistive humidity sensor.

6. The humidity sensor of claims 1 in which the detection electrodes are countersunk in the substrate.

7. The humidity sensor of claims 1 further comprising a passivation layer formed between the at least a detection electrode and the moisture-sensitive layer.

8. The humidity sensor of claims 1 in which the moisture sensitive layer is formed by an oblique-angle physical vapor deposition process.

9. The humidity sensor of claims 1 in which the porous, photocatalytic metal oxide comprises one or more of an oxide of titanium, iron, silver, copper, tungsten, zinc, tin and strontium.

10. A humidity sensor comprising an insulating substrate, at least a detection electrode, a moisture-sensitive layer, and a source of light radiation.

11. The humidity sensor of claim 10 in which the at least a detection electrode comprises a pair of electrodes, and the humidity sensor is a capacitive humidity sensor.

12. The humidity sensor of claim 11 in which the pair of detection electrodes are interdigitated.

13. The humidity sensor of claim 12 in which the detection electrodes are each comb shaped.

14. The humidity sensor of claim 10 in which the at least a detection electrode is a single electrode and the humidity sensor is a resistive humidity sensor.

15. The humidity sensor of claims 10 further comprising a passivation layer formed between the at least a detection electrode and the moisture-sensitive layer.

16. The humidity sensor of claims 10 in which the moisture sensitive layer is formed by an oblique-angle physical vapor deposition process.

17. A method of making a humidity sensor, comprising:
forming at least a detection electrode on an insulating substrate; and
forming a moisture sensitive layer in contact with the detection electrode by oblique-angle physical vapor deposition.

18. The method of claim 17 in which the physical vapor deposition process comprises rotating the substrate during deposition.

19. The method of claim 17 in which the at least a detection electrode comprises a pair of detection electrodes.
